(19) United States
(12) Patent Application Publication
(10) Pub. No.: US 2009/0278125 A1
(43) Pub. Date: Nov. 12, 2009

(54) CRYSTALLINE SEMICONDUCTOR FILMS, GROWTH OF SUCH FILMS AND DEVICES INCLUDING SUCH FILMS

(76) Inventors: Xiangfeng Duan, Los Angeles, CA (US); Xidong Duan, Changsha (CN)

Correspondence Address: Xiangfeng Duan, Apt #403, 715 Gayley Avenue, Los Angeles, CA, 90024, US

(21) Appl. No.: 12/425,391

(22) Filed: Apr. 17, 2009

Related U.S. Application Data
(60) Provisional application No. 61/124,443, filed on Apr. 17, 2008.

(51) Int. Cl. H01L 29/04; H01L 21/20

(52) U.S. Cl. 257/49; 438/488; 257/E29.003; 257/E21.09

(57) ABSTRACT

The present invention describes an approach to grow highly crystalline semiconductor films, multilayers of semiconductor thin films on foreign substrate such as glass, quartz. Specifically, The film were grown by first forming crystalline seeds, and transferring the seeds onto the substrate, and growing continuous semiconductor film through epitaxial growth on the seeds.

### RELATED APPLICATIONS

This application claims priority to U.S. Provisional Patent Application Ser. No. 61/124,443, entitled, “CRYSTALLINE SEMICONDUCTOR FILMS, GROWTH OF SUCH FILMS AND DEVICES INCLUDING SUCH FILMS”, filed Apr. 17, 2008;

### FIELD OF THE INVENTION

The present invention relates generally to crystalline thin films, and the approach to form crystalline semiconductor thin films on a foreign substrate, growth of multilayers of semiconductor thin film on a foreign substrate, doped to provide n-type and p-type conductivity, and the fabrication of electronic or optoelectronic devices from such thin films.

### BACKGROUND

Semiconductor devices are typically fabricated in the format of semiconductor wafers, which are slices of bulk crytstalline boules of certain semiconductor materials. The growth of semiconductor boules typically happens at high temerapture above the melting point of the semiconductor materials. For example, very large silicon boules can be growth above 1400° C., from which 12-inch wafers can now be readily produced. The ability to produce semiconductor wafer has been the main driving force for the continued cost-reductuon in silion based electronics. An alterntiave approach to grow crystalline semiconductor material is chemical vapor deposition (CVD) of thin film semiconductor materials, which however typically requires a substrate material that has matched lattice contstant and thermal propties in order to produce high quality material. Substrate made from same semiconductor wafers is the best subtrate for epitaxial thin film growth due perfect lattice and thermal expansion matching. CVD is a flexible approach to produce high quality crystalline thin film on substrate with controlled chemical composition and doping modulation to introduce device function into the thin film materials.

The advantage of compound semiconductors (e.g. gallium nitride, or gallium arsenide) is well known, and holds much promise for a wide range of applications in electronics (high frequency high power devices and circuits) and optoelectronics (lasers, light-emitting dides, solid state lighting). Despite the significant interest in these materials, their market capitalization is far less when compared to silicon electornics. One major reason for this is the difficulties involved in growth of large boules or wafers from compound semiconductor materials due to the dissociation of the semiconductors before metling. For example, GaN begins to dissociates at 900° C. while has a melting point of 2200° C. Therefore, it is extremely difficult to grow boules of GaN. Impeded by the absence of commercially viable bulk GaN wafers, signifincantly efforts have been focused on heteroepitaxial of GaN and related material (e.g., AlGaN, InGaN) on foreign substrate material. Two important factors need to be considered while slecting a foreign material as the substrate: lattice constant and thermal exapnasion coefficient. The substrates mostly commonly used for III-V nitride materials are sapphire and silicon carbide. However, these substrate are extremely costly (sapphire substrate is typically 10 times more expensieve the silicon wafers, and SiC is 100 time more expensive). Additionally, due to imperfect lattice and thermal expansion match. III-V nitride materials grown on these foreign subsrate often has large number of misfit dislocations (e.g. typical defect density 10e¹²/cm²), and therefore limits the performance of the materials and devices. There have been significant efforts in developing approaches to growth compound semiconductor materials on foreign substrate (e.g. Si), which however, require compliated intervening layer to relieve the lattice and thermal expansion mismatching, and only have limited success so far. Therefore, approaches that can grow high quality crystalline compound semiconductor materials (e.g. GaN or GaAs) on a foreign substrate (e.g. Si, quartz, glass, steel, or plastics) has the potential the drammtically reduce the cost of compound semiconductor electronics and optoelectornics, and expand their application to a wide range of areas, and in general totally transoform the field of electronics and photonics.

### SUMMARY

In an embodiment, provided is a crystalline semiconductor thin film on a foreign substrate.

In one aspect of this embodiment, the semiconductor thin film comprises: a seeding layer from assembled preformed nanoscrystals or microcrystals; and one or multiple epitaxtally grown crystalline semiconductor layers that comprising the same or different matcriald than the seeding layer.

In various aspects of this embodiment and all the following embodiments, the semiconductor thin film comprises a semiconductor from a group consisting of: Si, Ge, Sn, Se, Te, B, Diamond, P, B—C, B—P(BP₆), B—Si, Si—C, Si—Ge, Si—Sn and Ge—Sn, SiC, BN/BP/BAs, AlN/AlP/AlAs/AlSb, GaN/GaP/GaAs/GaSb, InN/InP/InAs/InSb, ZnO/ZnS/ZnSc/ZnTe, CdS/CdSe/CdTe, HgS/HgSe/HgTe, BeS/BeSe/Be Te/MgS/MgSe, GeS, GeSe, GeTe, SnS, SnSe, SnTe, PbO, PbS, PbSc, PbTe, CuF, CuCl, CuBr, Cul, AgF, AgCl, AgBr, Agl, BeSiN₂, CaCN₂, ZnGeP₂, CdSnAs₂, ZnSnSb₂, CuGeP₃, CuSi₂P₃, (Cu, Ag)(Al, Ga, In, Tl, Fe)(S, Sc, Te)₂, Si₃N₄, Ge₃N₄, Al₂O₃, (Al, Ga, In)₂(S, Se, Te)₃, Al₂CO, and an appropriate combination of two or more such semiconductors.

In various aspects of this embodiment, the semiconductor thin film comprises a dopant from a group consisting of: a p-type dopant from Group III of the periodic table; an n-type dopant from Group V of the periodic table; a p-type dopant selected from a group consisting of: B, Al and In; an n-type dopant selected from a group consisting of: P, As and Sb; a p-type dopant from Group II of the periodic table; a p-type dopant selected from a group consisting of: Mg, Zn, Cd and Hg; a p-type dopant from Group IV of the periodic table; a p-type dopant selected from a group consisting of: C and Si; or an n-type selected from a group consisting of: Si, Ge, Sn, S, Se and Te.

In a second embodiment, provided is a general aproach to grow polycrystalline or nearly single crystalline semiconductor film on low cost substrate from a pre-deposited seeding layer.

In one aspect of this embodiment, the seeding layer comprising of a distributed array of sphereical or plolyhedron semiconductor particles, or one dimensional elongated semiconductor microstructures or nanostructures. In various optional features of this aspect, the seeds comprise of chemical synthesized colloid nanocrytals, nanoscale rods, wires, fiber or ribbons, and belts, etched nanostructures from a bulk semiconductor material, the seeds are distributed regualarly, or irregularly.

In another aspect of this embodiment, the semiconductor particles or elongated structures that function as seeding layer is synthesized through solution chemical synthesis, gas phage chemical synthesis or lihthographic etching.

In another aspect of this embodiment, the seeding particles are deposited onto subsrate using spin coating, chemical absorption, electrostatic absorption, biological complementary interaction, ink-jet printing, contact printing, lamination.

In various aspects of this embodiment, at least one portion of the seeding particle has a smallest width of less than 5 micrometers, or less than 1 micrometers, or less than 500 nanometers, or less than 200 nanometers, or less than 100 nanometers, or less than 70 nanometers, or less than 60 nanometers, or less than 40 nanometers, or less than 20 nanometers, or less than 10 nanometers, or even less than 5 nanometers.

In another aspect of this embodiment, the seeding particles are elongated, and a ratio of the length of the section to a longest width is greater than 4:1, or greater than 10:1, or greater than 100:1, or even greater than 1000:1.

In another aspect of this embodiment, the elongated seeding particles are organized in parallel with their long axis aligned along one direction or roughly along one direction.

In another aspect of this embodiment, the semiconductor thin films are grown through epitixial growth on the seeding layer, in which the epitaxial growth can be carried out in gas phase, liquid phase or solution phase.

In third embodiment, the semiconductor thin film is n-doped. In various optional features of this aspect, the semiconductor is either lightly n-doped or heavily n-doped.

In yet another aspect of this embodiment, the semiconductor thin film is p-doped. In various optional features embodiments of this aspect, the semiconductor thin film is either lightly p-doped or heavily p-doped.

In another aspect of this embodiment, the semiconductor film is polycrystalline or polycrystalline with particular crystal orientation aligned along one direction (for films grow from oriented elongate semiconductor seeds.

In another aspect of this embodiment, the semiconductor film is a single crystal or nearly single crystal.

In additional various aspects of this embodiment, the semiconductor is magnetic; the semiconductor comprises a dopant making the semiconductor magnetic the semiconductor is ferromagnetic; the semiconductor comprises a dopant that makes the semiconductor ferromagnetic; and/or the semiconductor comprises manganese.

In an aspect of this embodiment, the semiconductor is attached to a low cost substrate and can be reased from the subsate to obtain free-standing semiconductor film.

In another aspect of this embodiment, the semiconductor comprises: a first layer comprising a first semiconductor; and a second layer comprising a different material or same material of different doping than the first semiconductor.

In another aspect of this embodiment, the semiconductor comprises 1 layer, more than 1 layer, more than 2 layers, more than 5 layers, more than 10 layers, more than 20 layers of same or different semiconductors with same or different dopants.

In yet another embodiment, provided is a doped semiconductor film that is at least one of the following: polycrystalline, near single crystal film with a preferred crystallographic orientation aligned along one specific direction, or a single crystal.

In one aspect of this embodiment, the electrical carrier can travel along a particular direction in the semiconductor thin film with much reduced grain boundary scattering or without scattering.

In another aspect of this embodiment, the semiconductor film is capable of emitting light in response to excitation, wherein a wavelength of the emitted light is related to the composition. In optional features of this aspect: the wavelength of the emitted light is a function of the thickness.

In another embodiment, provided is a device comprising at least one crystalline semiconductor film, the the film is on a low cost substrate such as glass, grown from a pre-formed seeding layer on the substrate.

In various aspects of this embodiment, the device comprises one or more of the following: a switch; a diode; a Light-Emitting Diode; a tunnel diode; a Schottky diode; a Bipolar Junction Transistor; a Field Effect Transistor; an inverter; a complimentary inverter; an optical sensor; a sensor for an analyte (e.g., DNA); a memory device; a dynamic memory device; a static memory device: a laser; a logic gate; an AND gate: a NAND gate; an EXCLUSIVE-AND gate; an OR gate; a NOR gate; an EXCLUSIVE-OR gate; a latch; a register; clock circuitry; a logic array; a slate machine; a programmable circuit; an amplifier: a transformer; a signal processor; a digital circuit; an analog circuit; a light emission source; a photoluminescent device; an electroluminescent device; a rectifier; a photodiode; a p-n solar cell; a phototransistor; a single-electron transistor; a single-photon emitter; a single-photon detector; a spintronic device; a scanning tunneling microscope; a field-emission device; a photoluminescence tag; a photovoltaic device; a photonic band gap materials; and a circuit that has digital and analog components.

In various aspect of this embodiment, these above devices is ued in high speed electronics, high power electronics, display devices, illumination devices, white light sources, solar panels.

In yet another embodiment, the semiductor film is released from the growth substrate to be free standing or transferred onto another lower cost substrate (e.g. plastics).

In an aspect of this embodiment is the transfer of semiconductor film onto lower cost susbtrate and fabricated devices on those susbtrate.

In another aspect of this embodiment is the fabrication of devices on the growth substrate and and then transfer the devices onto lower cost susbtrate.

In another embodiment of this substrate is that the crystalline semiconductor film is transferred through lamination, contact printing.

In another aspect of this embodiment, the various devices described above are formed in the semiconductor films that were transferred to another substrate.

### BRIEF DESCRIPTION OF THE DRAWINGS

For a better understanding of the present invention, reference is made to the accompanying drawings, which are incorporated herein by reference and in which:

FIG. 1 is a schematic drawing illustrating growth of crystalline semiconductor film from distributed nano/microparticlc seeds;

FIG. 2 is a schematic drawing illustrating growth of crystalline semiconductor film from aligned elongated semiconductor seeds;

FIG. 3 is schematic drawing illustrating growth of crystalline semiconductor films from seeds with triangular cross section;

FIG. 4 is a schematic drawing illustrating example of devices made from the crystalline semiconductor films.

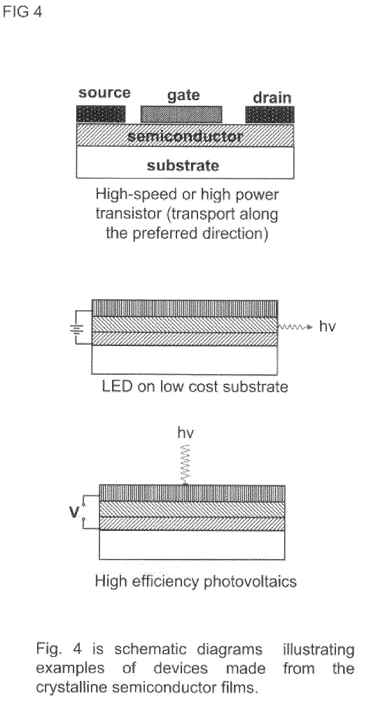

### DESCRIPTION AND EXAMPLES

The present invention provides, in one aspect, techniques for controlled growth of crystalline semiconductor films on broad substrates such as glass, quartz or silicon, and use such crystalline films to create useful devices.

In various embodiments, this invention involves controlled growth of crystalline doped semiconductor film on preformed seeding layer on a desired substrate, the semiconductor including, but not limited to gallium nitride, gallium arsenide, indium nitride, indium phosphide, cadmium selenide, and zinc selenide, and dopants including, but not limited to, zinc, cadmium, or magnesium can be used to form p-type semiconductors in this set of embodiments, and dopants including, but not limited to, tellurium, sulfur, selenium, or germanium can be used as dopants to form n-type semiconductors from these materials. These materials define direct band gap semiconductor materials that are well known to those of ordinary skill in the art. The present invention contemplates the growth and application such crystalline film for a variety of uses.

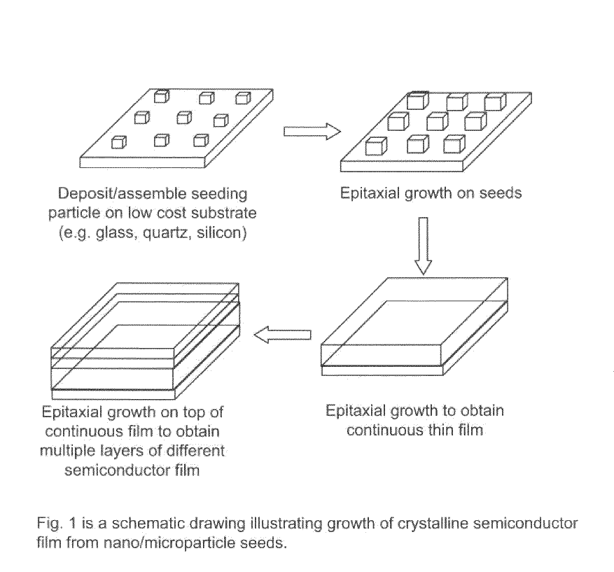

FIG. 1 isllustrates the growth of crystalline semiconductor film from an array of predeposited nanoparticle seeds. Here a monolayer or submonolayer of semiconductor particles is first deposited on the a chosen substrate (quartz, glass, SiO₂ or silicon), such nanoparticle on surface is then used as seeding layer to growth crystalline semiconductor film through an epitixial growth either in solution to in gas phage (e.g. chemical vapor deposition) to eventually obtain a continues crystalline semiconductor film, which can be further used as template to grow additional layers of same or different semiconductors with same or different doping, and can be used for various device fabrications.

The crystalline semiconductor film otanined this way is usually polycrystalline. However, it is also possible to obtain nearly single crystalline films if one organizes the nanoseeds with controlled crystallographic orientation. Such organization can be done with precisely controlled molecular recognition properties exploiting highly specific biomolecules or complemenary chemical interactions.

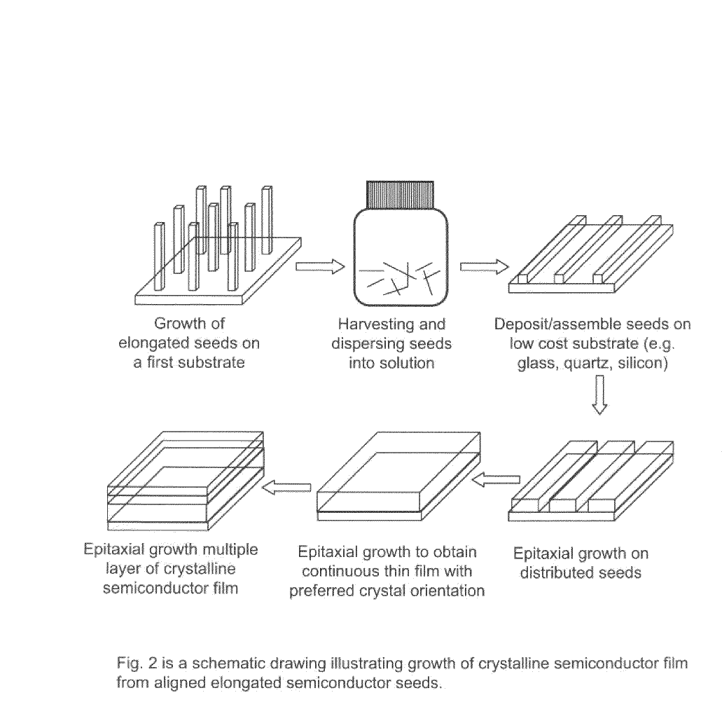

A second type of seeding layer is an array of elongated semiconductors objects (wires or fibers) (FIG. 2). Here single crystal wirs are first grown on a first susbtrate, and then were harvested and dispersed in solution and then assembled onto a second susbtrate with the wire axis aligned roughly along one direction. Such an array of wires was then used as the seeding layer for epitaixal growth of one or multiple layers of crystalline semiconductor films. In this case, since the the wires have a preferred crystallographic orientation, epitaxial growth on the oriented wires can lead to nearly single crystal film at least along the wire axis direction. Such preferred crystallographic orientation can lead to many advantages for device applications such high speed transistors with conducting channel along the single crystalline direction. We note the nanowire seeds don't have to be grown on a first substrate, it can be grow in solution or obtained through lithographic etch as well. Additionally, by controlling the crystallographic orientation of of wire seeds, and the crystallographic orientation specific assembly, one can also rationally tune the reltative epitaxial growth rate along the vertical or lateral dimension as needed. For example, preferred lateral overgrowth can accerlerate the formation of a continuous thin film.

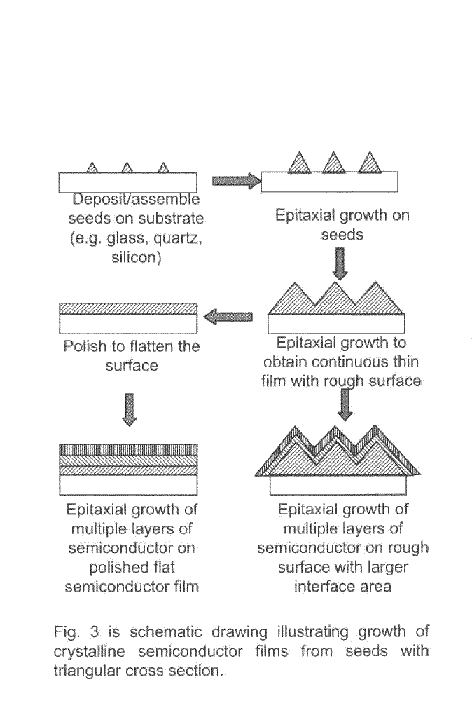

For illustration purpose, we have focused on seeding particles with a square cross section, although seed particle of many different morphologies (triangular, sphereical, hexagonal, polyhedron . . . ) maybe used, and epitaxial growth on these seeds can lead to rough surfaces (e.g. FIG. 3), which can be, flatten through a polishing process, or used as templated without additional polishing, as the rough surface can increase the interface area and lead to other advantages in device applications. For example, the increased interface area can allow more efficient charge separation in photovoltaics devices, and the surface roughness may reduce the relfection and therefore increase the overall efficiency of the photovoltaics devices. For another example, the increased interface area can enable more reliable electrically driven light emitting devices with same brightness under less current injection density across the interface.

With epitaxial growth from the distributed seeds, the semiconductor film is epxeted to have good crystallinity. Using organized nanoseeds, it is possible to achieve semiconductor film with nearly perferet crystalline structure like single crystals. The epitaxial growth from distributed seeds can also reduce the instrinsic strain and lead to crystalline films with less defects. Since nanoseeds can be deposited on a wide range fo substrates including glass, quartz or silicon, it will enabled an entirely new and general path way to grow a wide range of technoligcally important materials on these substrates, and therefore enable a whole new range of applications. For example growth of III-V semiconductors (e.g. GaN, InN, GaP, InP, GaAs and InAs etc or combination of them) on glass or silicon substrate can enable a whide range of high speed or high power transistors (Metal Oxide semiconductor Field Effect Transistors or Metal Semiconductor Field-Effect Transistors). Growth of multiple layers of III-V and II-VI semiconductors films with controlled doping to composition modulaton will enable a wide range of optoelectronic devices such as photovoltaic device for energy harvesting or light emitting device for solid state display or white light illumination on large area cheap substrate (e.g. silicon, glass or quartz). Lastly, the crystalline film grown glass, quartz may also be removed from the substrate to form free standing devices or transferred onto other substrate such as plastics and metal foils to obtain flexible electronics, optoelectronics. This approach can be used to make all the existing types of semiconductor thin films and fabricate devices from such thin films. The following are potential applications:

(1) Light emitting devices

(2) Solid state displays

(3) White-light bulb

(4) Lasers

(5) Indicating tag using the photoluminescence properties

(6) Photovoltaic solar cells

(7) Photodetector and polarized light detector

(8) High speed electronics

(9) High power electronics

(10) Flexible electronics/optoelectronics

Having now described some illustrative examples of the invention, it should be apparent to those skilled in the art that the foregoing is merely illustrative and not limiting, having been presented by way of example only. Numerous modification and other illustrative embodiments are within the scope of one of ordinary skill in the art and are contemplated as falling within the scope of our description. In particular, although the examples presented herein involve specific combinations of method acts or system elements, it should be understood that those acts and those elements may be combined in other ways to accomplish the same objectives. Acts, elements and features discussed only in connection with one embodiment of a system or method are not intended to be excluded from a similar role in other embodiments. Additionally, the approach described here can be readily extended to any crystalline films including metallic, superconducting, magnetic, optical and dielectric films.

What is claimed is:

1. A method tor growing crystalline semiconductor film on a substrate, the method comprising of forming crystalline semiconductor seeds, depositing seeds on substrate to obtain a distributed array of seeds on substrate, epitaxial growing semiconductor on the seeds that merge together to form a continuous semiconductor film on substrate.

2. The seeds in claim 1 comprise of nanoparticles, microparticles, or polyhedron particles.

3. The seeds in claim 1 comprise of free-standing elongated structures, including nanowires, microfibers, ribbons, belts.

4. The seeds in claim 1 are nanowires grown from metal-nanocluster catalyzed approach.

5. The seeds in claim 1 at least have one portion with the smallest width less than 100 nm.

6. The seeds in claim 1 are formed by chemical synthesis.

7. The seeds in claim 1 are formed by lithographic etch.

8. The distributed array of seeds in claim 1 is obtained by depositing preformed free-standing nanostructures or microsctrucfures.

9. The distributed array of seeds in claim 1 is nanowire array aligned along one direction.

10. The distributed array of seeds in claim 1 is obtained by localized growth on selected locations on substrate.

11. The crystalline semiconductor film in claim 1 is polycrystalline.

12. The crystalline semiconductor film in claim has anistropic crystallinity, with direction have nearly single crystalline order and the other have more grain boudaries.

13. The semiconductor is claim 1 is a compound semiconductor and its alloy.

14. The semiconductor is claim 1 is gallium nitride and its alloy.

15. The semiconductor is claim 1 is indium phosphide and its alloy.

16. The substrate is in claim 1 is glass or silicon nitride.

17. A device fabricated from crystalline semiconductor film, where the film is grown using epitxial growth on distributed seeds.

18. The device is claim 13 is a transistor.

19. The device is claim 13 is light-emitting diode.

20. The device is claim 13 is a photovotics device.
